(19) United States
(12) Patent Application Publication
(10) Pub. No.: US 2010/0101627 A1
(43) Pub. Date: Apr. 29, 2010

(54) FLEXIBLE SOLAR PANEL MODULE

(76) Inventor: Pradyumna V. Patel, Southlake, TX (US)

Correspondence Address: BANOWSKY &LEVINE, P.C, 12001 N. CENTRAL EXPRESSWAY, SUITE 790, DALLAS, TX, 75243, US

(21) Appl. No.: 12/605,363

(22) Filed: Oct. 25, 2009

Related U.S. Application Data
(60) Provisional application No. 61/197,561, filed on Oct. 26, 2008.

(51) Int. Cl. H01L 31/042

(52) U.S. Cl. 136/244

(57) ABSTRACT

The present invention provides a flexible solar panel which can be used as to provide a standalone power generation solution or simply to supplement power provided by a traditional utility provider. It is designed to withstand inclement weather. It uses semi-spherical photovoltaic amorphous, poly silicon or single crystalline semiconductor materials like Silicon to produce electrical energy from sunlight. Each photovoltaic cell is mounted on a flexible printed circuit board to create the usable power source. The flexible printed circuit boards are embedded in low durometer substrate materials like Neoprene and then covered with a clear protective film.

### CROSS-REFERENCE TO RELATED APPLICATION

This application claims priority to provisional application No. 61/197,561, filed on Oct. 26, 2008, which application is incorporated herein by reference.

### FIELD OF INVENTION

Electrical power is generated by the electric utilities, electricity producers, commercial users and industrial users. The electric power industry is a $298-billion industry that provides a vital service essential to modern life. Photovoltaic power (Solar) is one of the best ways to produce green electrical power from sunlight. Photovoltaic power is the fastest energy-producing sector of the electric power industry. However, the cost per kilowatt hour associated with current solar technologies have prevented its widespread adoption as a primary source of power generation. Much of the high cost of solar power is involved in the manufacture and installation of the traditional rigid solar panel, rather than the manufacture of the actual solar cell. The present invention presents a novel approach to the design and manufacture of flexible solar panel modules, using existing solar cell technologies, to greatly enhance the economic viability of solar power generation.

### BACKGROUND OF INVENTION

The invention pertains generally to the design and manufacture of a flexible solar panel module. The solar panel is a device that is used in converting sunlight into electrical power. The main component in a solar panel is a photovoltaic cell. Sunlight contain packets of energy known as photons. The energy contained in the photons present in visible light excite electrons in a semiconductor material, thus creating a voltage differential.

The two major photovoltaic technologies are the polysilicon solar cell and the thin film solar cell. Thin film technology involves depositing photosensitive material on a plastic, metal or glass substrate. It is the more cost effective way of the two technologies to manufacture a photovoltaic cell. However, it suffers from a lower efficiency than the polysilicon solar cell. The more conventional, and more expensive, process to create a photovoltaic cell is with diffusion of p and n type dopants into a polysilicon wafer to create the photosensitive diode. The photosensitive diode converts light into a voltage differential which can be used to generate electrical power. Existing polysilicon solar panels are typically made from brittle silicon wafers, which can easily crack rendering them ineffective. Silicon cells on traditional solar panels may not be replaced if they malfunction thus reducing the overall efficiency of the solar panel.

The present invention uses existing photovoltaic cell technologies and implants them into a flexible substrate thereby creating a flexible solar panel which is both more durable than existing solar panel technologies and also less expensive to manufacture and install. The objective of the present invention is to design and manufacture affordable solar panels to provide a complete integrated solution for supplemental power to the consumer. The present invention offers the following advantages: (1) cost effectiveness; (2) durability; (3) ease of installation; (4) and ease of maintenance.

### BRIEF DESCRIPTION OF DRAWINGS

FIG. 1 is a flexible solar panel module.

FIG. 2 is an exploded view of a flexible solar panel module

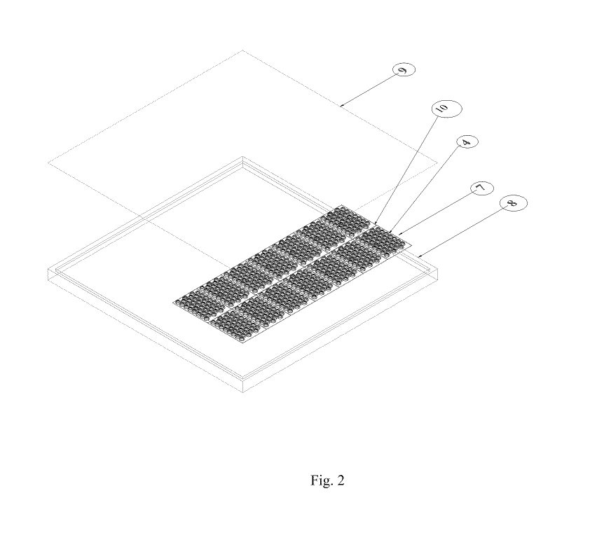

FIG. 3 is an assembly view of a flexible printed circuit board.

FIG. 4 is a flexible printed circuit board.

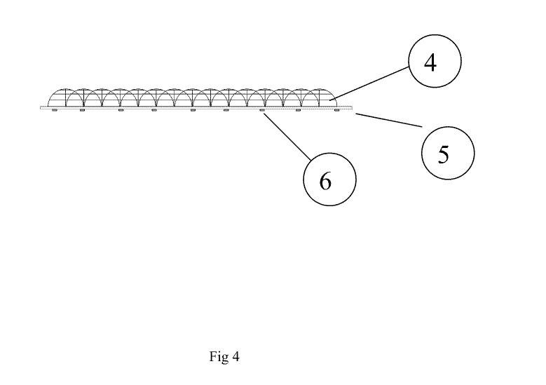

FIG. 5 is a semi-spherical solar cell.

FIG. 6 is a semi-spherical solar cell.

FIG. 7 is a detailed view of a typical flexible printed circuit board schematic.

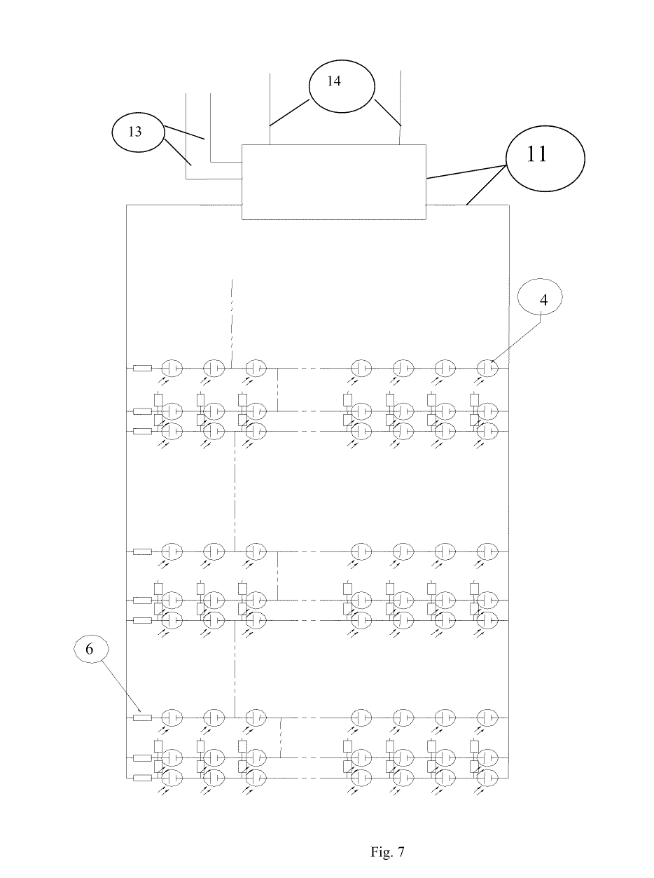

FIG. 8 is a typical installation of a flexible solar panel grid.

FIG. 9 is a detailed view of the mounting and interconnect elements of a flexible solar panel module.

### DETAILED DESCRIPTION OF THE INVENTION

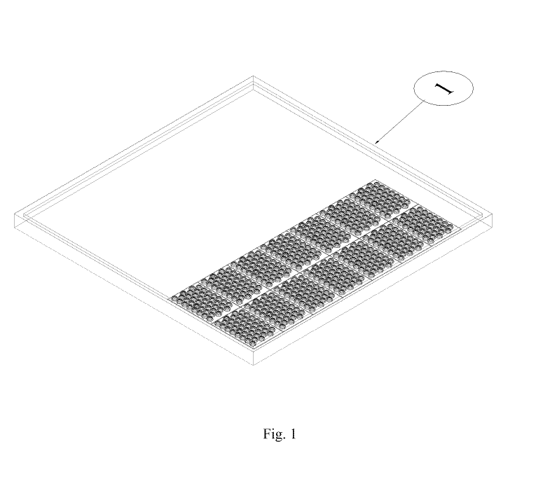

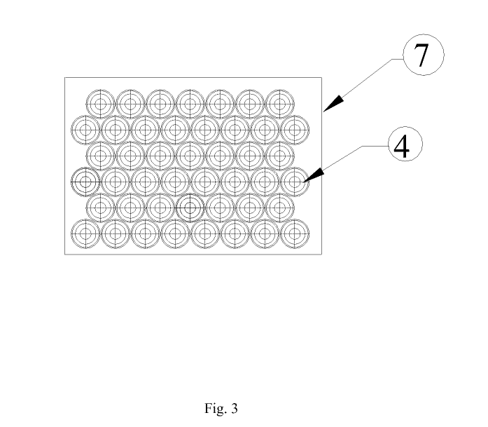

The flexible solar panel module 1 is depicted in FIG. 1. The flexible solar panel module 1 is comprised of one or more flexible printed circuit board modules 10 mounted on a flexible substrate 8 and covered with a protective film 9. Each flexible printed circuit board module 10 is comprised of one or more thin flexible printed circuit boards 5 onto which is mounted an array of semi-spherical photovoltaic cells 4 and a circuit protection module 6 to optimize performance and protection against potential over voltage and/or current. The assembled flexible printed circuit board 7 is depicted in FIG. 3. Additionally, DC to AC power conversion circuitry 11 may also be mounted on the flexible printed circuit board 5.

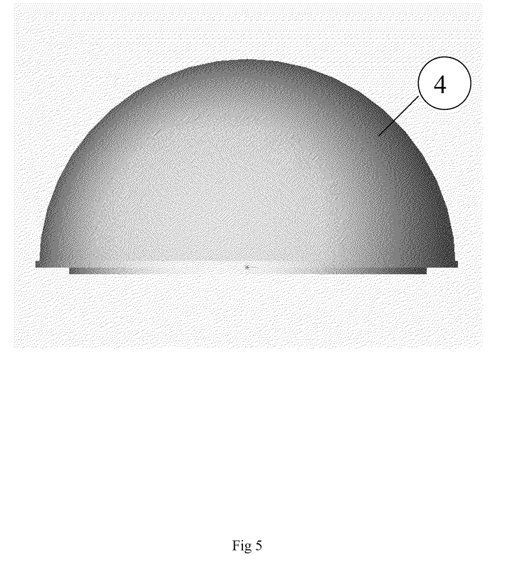

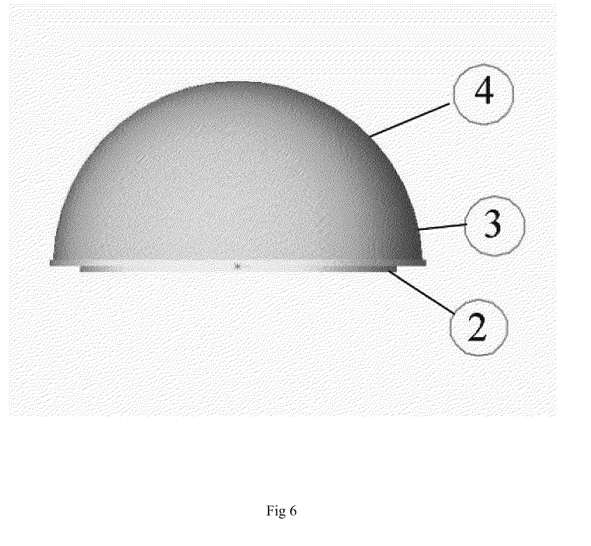

In a preferred embodiment, a photovoltaic cell 4 (FIG. 5 and FIG. 6) is constructed from a single crystalline or crystalline or amorphous p-type semiconductor semispherical material like silicon or germanium. The n-type is deposited on the p-type material to create an anode 2 and a cathode 3 for the semispherical photovoltaic cell 4. The semispherical photovoltaic cell 4 is sealed with an oxide or nitride process and covered with a non reflective layer to aid light absorption. Alternatively, the photovoltaic cell 4 can be fabricated using an n-type substrate that creates a cathode and a p-type material to create an anode deposited on the n-type substrate material.

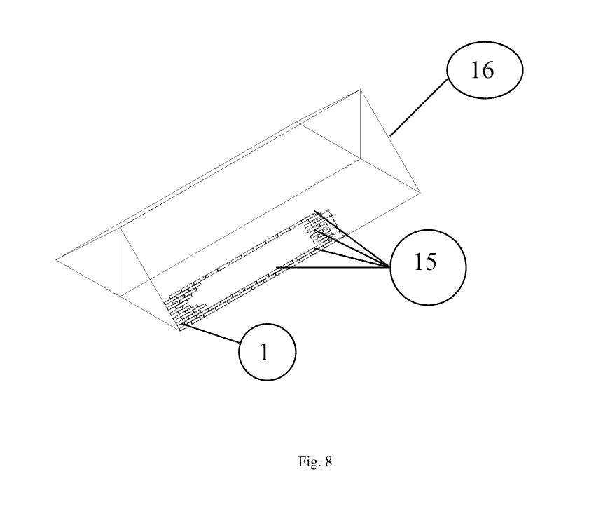

A flexible solar panel grid 15 is depicted in FIG. 8. The flexible solar panel grid is comprised of two or more flexible solar panel modules 1. In a typical installation, one or more flexible solar panel grids 15 are installed on the roof 16 of an existing structure, either on top or, or in lieu of, traditional roofing materials. A power bus transmits power from the flexible solar panel grid(s) 15 to the electrical system of the structure.

A preferred embodiment of the present invention uses semi-spherical p-type polysilicon solar cells 4. The semi-spherical photovoltaic cells 4 provide larger surface area for the sunlight to react, and a larger junction area. They are also easy to manufacture on relatively inexpensive equipment. The semi-spherical photovoltaic cells 4 are mounted on a flexible circuit board 5. The flexible circuit board 5 includes protection against electrical short and open circuits by virtue of a current and voltage protection module 6. The power conversion from direct current (DC) to alternating current (AC) is accomplished through a DC/AC conversion module 11 which is integrated into the flexible circuit board module 10. There are a number of ways to accomplish current and voltage protection and DC/AC current conversion which are well known to someone skilled in the art. In a preferred embodiment, each photovoltaic cell is individually affixed to the flexible circuit board allowing defective photovoltaic cells to be discarded and maximizing the overall efficiency of the flexible solar panel module. As a result of the DC/AC conversion module 11, the output from this embodiment of the flexible circuit board module 10 is AC, as opposed to the DC power normally associated with conventional rigid solar panels. Of course, deletion of the DC/AC conversion module 11 will result in AC power output.

In this preferred embodiment, one or more flexible circuit board modules 7 are embedded onto a flexible Neoprene substrate 8 and then covered by a clear film 9 to form a flexible solar panel module 1. In this preferred embodiment, the clear film 9 has a high level of light transmittance in the operating wavelength range of the semi-spherical photovoltaic cells 4 and is manufactured such that it offers flexibility, mechanical strength, and reliability.

Two or more flexible solar panel modules 1 can be interconnected to form a flexible solar panel grid 15. The flexible solar panel grid 15 can be installed on a roof 16 of a new or existing structure to provide electrical power. Alternatively, the flexible solar panel grid 15 can be installed on the wall of the structure. Two or more flexible solar panel grids 15 can be interconnected by an electrical bus to combine the voltages of the flexible solar panel grids 15 and transmit the collected energy to the electrical system of the structure or directly into the utility company's electric grid.

Although the use of semi-spherical photovoltaic cells is desirable due to the increase in efficiency obtained thereby, it should be understood that the flexible solar panel module 1 can be manufactured using any of a number of photovoltaic cells which are known in the art. Likewise, although the use of Neoprene is desirable because of its flexible, strength and ability to withstand the detrimental effects of ultraviolet radiation, it should be understood that the flexible solar panel module 1 can be manufactured using any number of low durometer substrate materials which are known in the art.

The flexible solar panel module 1 described herein is designed to withstand abuse and inclement weather like hail, rain, snow and wind. In the preferred embodiment, the flexible solar panel module 1 is constructed with small photovoltaic cells of about 1 mm diameter polysilicon semi spheres rather than the conventional brittle silicon wafers. The inherent property of the semi-spherical design of the photovoltaic cells provides excellent fractural strength. The small semi-spherical photovoltaic cells 1 provide mechanical flexibility to the flexible solar panel module 1. The flexible circuit board 5 and low durometer substrate material like Neoprene 8 provide ruggedness and flexibility to the small photovoltaic cells used in the flexible solar panel module 1 against abuse and inclement weather. In addition to its other qualities, Neoprene offers excellent protection against the UV radiation present in sunlight.

The flexible solar panel module 1 is intended to be mounted on the roof of a structure and includes reinforced mounting holes 12 to provide the strength against wind and inclement weather. In the preferred embodiment, the size of each flexible solar panel module is approximately 36″×6″×½″ thick to match the size of the shingles used on a typical residential roof. Of course, it should be understood that the modular nature of the present invention lends itself to being manufactured in any number of different dimensions. Each flexible solar panel module 1 will be mounted on the shingles with roofing nails. Each flexible solar panel module 1 is easily interconnected with other flexible solar panel modules 1 to create a solar panel grid 15 which is capable of providing substantial electrical power to the consumer. The electrical power generated from the flexible solar panel grid 15 is in sync with the electrical power provided by the local utility company.

The flexible solar panel module 1 is designed to have the least amount of maintenance. In the preferred embodiment, the material used for the clear film 9 is selected such that it has a very low surface energy resulting in a product that will resist becoming dirty and is easy to clean. In the preferred embodiment, the protective film 9 is manufactured from clear thermoplastics. Clear thermoplastics are used because of their superior mechanical strength, flexibility, toughness, excellent chemical resistance and dielectric properties. Although the use of clear thermoplastics is desirable, it should be understood that the protective film 9 can be manufactured from any number of transparent or translucent materials which are known in the art. The film has good cut through resistance, tear strength and excellent weathering performance.

The flexible solar panel grid 15 is designed with a modular concept, so any damaged flexible solar panel module 1 can be removed from the flexible solar panel grid 15 and easily replaced in minutes. The semi-spherical photovoltaic cells 4 allow for the elimination of defective photovoltaic cells during the manufacturing process, to improve the overall efficiency of the flexible solar panel module 1. The semi-spherical photovoltaic cells 4 minimize the stiffness and brittleness of the material used to manufacture the flexible solar panel module 1 and improves its overall strength against abuse and inclement weather. The flexible printed circuit boards 5 allow any photovoltaic cells damaged by abuse or inclement weather to be disabled. The flexible printed circuit boards 5 add mechanical flexibility to the flexible solar panel module 1. The flexible printed circuit boards 5 minimize the brittleness of the material used in the manufacturing of the flexible solar panel module 1 thereby improving the overall strength of the flexible solar panel module 1 against abuse and inclement weather. The low durometer material 8, like Neoprene, also minimizes the stiffness and brittleness of the material used to manufacture the flexible solar panel module 1 and improves its overall strength against abuse and inclement weather. The low durometer material 8, like Neoprene, provides protection to the electrical components used to produce the flexible solar panel modules. The low durometer material 8, like Neoprene, facilitates ease in mounting the flexible solar panel modules.

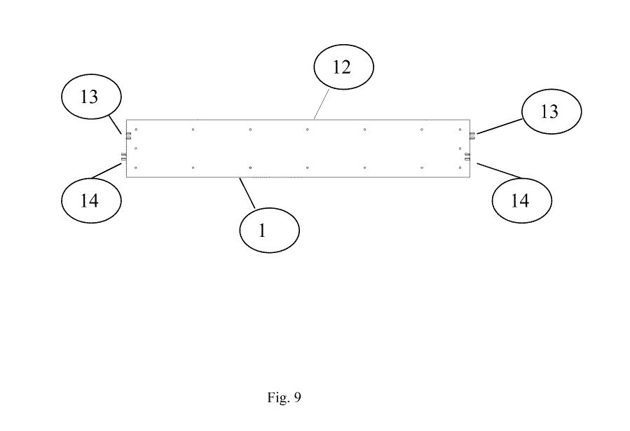

FIG. 9 depicts the mounting elements of the flexible solar panel module 1. The flexible solar panel module 1 consists of mounting holes 12, to accept roofing nails or other mounting hardware, control connections 13, including pins for the input and output configurations, and power connections 14, including pins for the output of power from the flexible solar panel module 1 and pins for input of power from other flexible solar panel modules 1.

Although the invention has been described in detail with reference to a particular embodiment, it is to be understood that variations or modifications may be made within the spirit and scope of the invention as defined in the appended claims.

What is claimed is:

1. A flexible solar panel module comprising:
an array of photovoltaic cells;
one or more flexible printed circuit boards onto which the array of photovoltaic cells is mounted;
a low durometer substrate material onto which the flexible circuit boards are mounted;
a protective film covering the array of photovoltaic cells;
a means of protecting against electrical short and open circuits; and
a means of converting direct current to alternating current.

2. The flexible solar panel module of claim 1 wherein the array of photovoltaic cells is comprised of semi-spherical photovoltaic cells.

3. The flexible solar panel module of claim 2 wherein the semi-spherical photovoltaic cells are produced from p-type semiconductor materials.

4. The flexible solar panel module of claim 2 wherein the semi-spherical photovoltaic cells are produced from amorphous, poly silicon or single crystalline materials.

5. The flexible solar panel module of claim 2 wherein the semi-spherical photovoltaic cells are fabricated from n-type poly silicon on p-type semi-spherical substrate material.

6. The flexible solar panel module of claim 3 wherein the p-type semiconductor material is silicon.

7. The flexible solar panel module of claim 1 further comprising:
a means of mechanically connecting the flexible solar panel module to a structure;
a means of mechanically connecting the flexible solar panel module to one or more other flexible solar panel modules; and
a means of electrically connecting the flexible solar panel module with one or more other flexible solar panel modules.

8. A flexible solar panel grid comprising:
two or more flexible solar panel modules of claim 7; and
a means of transmitting power generated within the flexible solar panel modules to an external load.

9. The flexible solar panel grid of claim 8 wherein the means of transmitting power generated within the flexible solar panel modules to an external load is an electrical bus.
